(19) United States
(12) Patent Application Publication
(10) Pub. No.: US 2024/0258244 A1
(43) Pub. Date: Aug. 1, 2024

(54) METHODS FOR MECHANICAL SELF-ALIGNMENT AND SLIP-RESISTANCE IN BONDING SEMICONDUCTOR SUBSTRATES, AND SEMICONDUCTOR DEVICES COMPRISING MECHANICAL SELF-ALIGNMENT STRUCTURES

(71) Applicant: Micron Technology, Inc., Boise, ID (US)

(72) Inventor: Joanna Nassar, Cupertino, CA (US)

(21) Appl. No.: 18/403,007

(22) Filed: Jan. 3, 2024

Related U.S. Application Data
(60) Provisional application No. 63/442,383, filed on Jan. 31, 2023.

(51) Int. Cl. H01L 23/544; H01L 21/82

(52) U.S. Cl. CPC H01L 23/544; H01L 21/82; H01L 2223/54426; H01L 2223/5446

(57) ABSTRACT

A method for mechanical self-alignment and slip-resistance in bonding semiconductor substrates is provided. The method includes providing a first semiconductor substrate with a first surface and a second semiconductor substrate with a second surface. Next, the method includes etching a first mechanical alignment structure into the first surface and then etching a second mechanical alignment structure into the second surface, such that the first and second mechanical alignment structures are topographically inverse. What follows is optically aligning the first substrate to the second substrate, such that the first and second surface face one another, and then bringing the substrate surfaces into contact. Next, the substrates mechanically self-align, such that the topographically inverse structures inter-fit. Finally, the method includes bonding both substrates, such that planar bonding regions form between the surfaces and slanted bonding regions form between the mechanical alignment structures.

### CROSS-REFERENCE TO RELATED APPLICATION(S)

The present application claims priority to U.S. Provisional Patent Application No. 63/442,383, filed Jan. 31, 2023, the disclosure of which is incorporated herein by reference in its entirety.

### TECHNICAL FIELD

The present disclosure generally relates to semiconductor device assemblies, and more particularly relates to methods for mechanical self-alignment and slip-resistance in bonding semiconductor substrates, and semiconductor devices comprising mechanical self-alignment structures.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIG. 1 is a simplified schematic cross-sectional view of an example semiconductor device assembly.

FIG. 2 is a schematic view illustrating a process of making an incorporated semiconductor apparatus in accordance with embodiments of the present technology.

FIG. 3 is a simplified schematic cross-sectional view of an incorporated semiconductor apparatus in accordance with embodiments of the present technology.

FIG. 4 is a simplified cross-sectional view of a section of a semiconductor apparatus in accordance with embodiments of the present technology.

FIGS. 5-6 are simplified schematic cross-sectional views of a section of a semiconductor apparatus in accordance with embodiments of the present technology.

FIG. 7 is a partial schematic oblique view of a semiconductor apparatus in accordance with embodiments of the present technology.

FIG. 8 is a schematic view of a semiconductor wafer in accordance with embodiments of the present technology.

FIG. 9 is a schematic view showing a system that includes a semiconductor device assembly configured in accordance with an embodiment of the present technology.

FIG. 10 is a flow chart illustrating a method of making a semiconductor device assembly in accordance with an embodiment of the present technology.

### DETAILED DESCRIPTION

The electronics industry relies upon continuous innovation in the field of semiconductor packaging to meet the global need for higher-functioning technology. This demand calls for semiconductor device assemblies that are increasingly compact and increasingly complicated in their design, but which must meet the same production costs as before.

One approach to meet this challenge is the Wafer-on-Wafer process (WoW). WOW entails bonding entire wafers together before dicing them into their singulated die assemblies. The benefits of this process are increased density and throughput in the assemblies, as well as reduced costs in production.

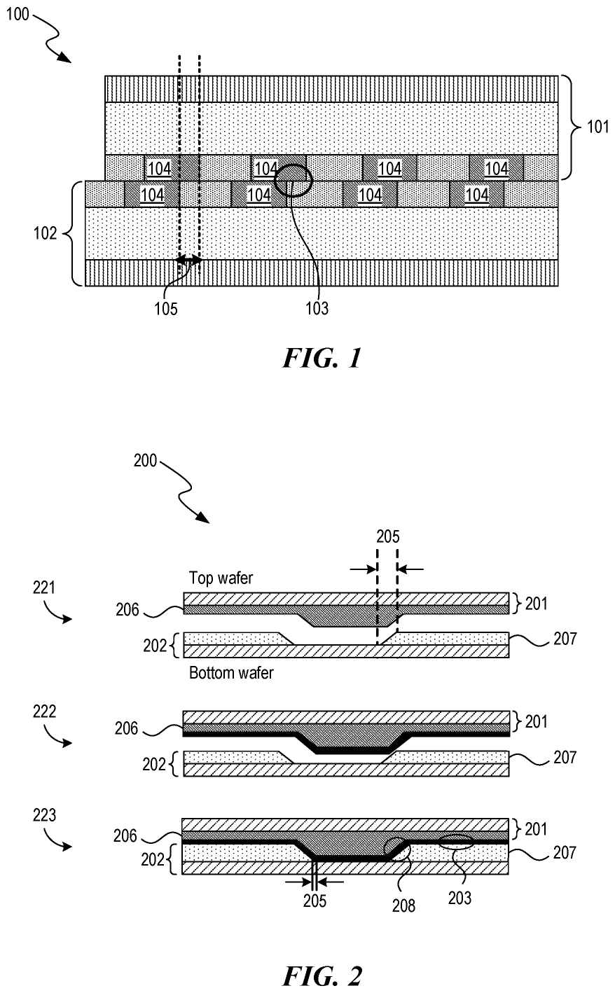

FIG. 1 illustrates an example of a semiconductor device assembly 100 formed by a first substrate 101 stacked over a second substrate 102. However, in order for both substrates to form a planar bonding region 103, they must be correctly aligned. Considering the density of connections 104 which must form between the two substrates, this is a difficult challenge.

Current methods for overcoming this problem include optical alignment techniques (wafer backside alignment marks, infrared transmission microscopy, inter-substrate microscopy, transparent substrate, or through-wafer holes in combination with optical microscopy, etc.). Optical alignment techniques, however, cannot account for the stress-induced misalignment 105 of wafers that occurs post optical alignment. After both wafers have been placed in contact, the wafers experience further thermal and mechanical processes (bonding, thinning, grinding, polishing, interconnect or redistribution layer formation, TSV formation, etc.) which can cause the wafers to warp and become misaligned. These misalignments 105 cause weaker bonds 103 between the two wafers, which could result in the assembly 100 not functioning as designed, or could result in damage to the assembly 100.

To address these drawbacks and others, various embodiments of the present application provide methods for mechanical self-alignment and slip-resistance in bonding semiconductor substrates, and the topographically inverse surface structures for facilitating the same. FIG. 2 illustrates a method for mechanical self-alignment and slip-resistance in bonding semiconductor substrates 200. The method starts by providing a first semiconductor substrate 201 that has a first surface 206, and a second semiconductor substrate 202 that has a second surface 207. Next, a first mechanical alignment structure is etched into the first surface 206, and a second mechanical alignment structure is etched into the second surface 207, such that the first and second mechanical alignment structures are topographically inverse. These structures are viewed in greater detail in later Figures. The next step in the method includes optically aligning the first substrate 201 to the second substrate 202, such that the first and second surface 206 and 207 face one another (step 221). Similar to FIG. 1, a misalignment exists between the substrates 205. However, according to the disclosed method 200, when the wafer surfaces are brought into contact (step 222), the substrates mechanically self-align such that the topographically inverse structures inter-fit, and the misalignment 205 between substrates is reduced. Finally, the substrates are bonded (step 223) to form an incorporated semiconductor apparatus, such that planar bonding regions 203 form between the surfaces and slanted bonding regions 208 form between the mechanical alignment structures. These additional bonding regions reduce the likelihood of lateral slippage between the substrates due to thermal and mechanical forces imposed on the assembly by manufacture. Additionally, the first and second surfaces 206 and 207 can have a micro-patterning to further reduce slippage between the substrates 201 and 202 and improve bonding 203 and 208. The first and second surfaces 206 and 207 can also comprise at least one of the following: a dielectric material, an oxide, silicon, or an electrically conductive material (e.g., Copper). Furthermore, in the method at least one of the substrates 201 or 202 can be a wafer, which combine to form an incorporated semiconductor apparatus, and the method can further comprise dicing the incorporated semiconductor apparatus to form a stacked semiconductor device assembly.

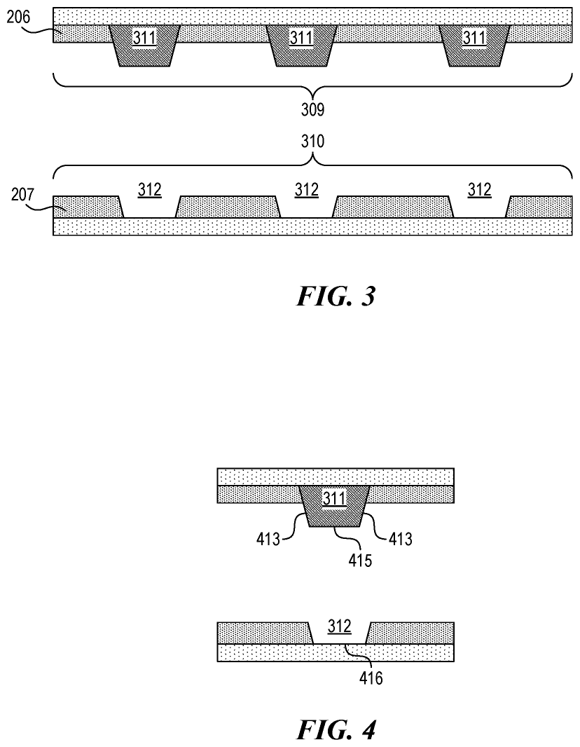

Contributing to these slanted bonding regions 208, FIG. 3 illustrates a first mechanical alignment structure 309 belonging to the first surface 206 and a second mechanical alignment structure 310 belonging to the second surface 207. The first mechanical alignment structure 309 has protrusions 311 while the second mechanical alignment structure 310 has grooves 312, the protrusions 311 fitting inside the grooves 312 as the second surface 207 comes into contact with the first surface 206, forming the planar and slanted bonding regions 203 and 208.

Exploring these features in greater detail, FIG. 4 reveals the protrusions 311 have sides 413 and a top 415, whereas the grooves 312 have sidewalls 414 and a bottom 416. As the planar bonding regions 203 form between the first and second surface 206 and 207, the slanted bonding regions 208 form between these sides 413 and sidewalls 414. The sides 413 of the protrusions can come into contact with the sidewalls 414 of the grooves, or the protrusions 311 can be slightly narrower than the grooves 312 to allow for thermal expansion. The sides 413 can be atomically bonded with the sidewalls 414 to form a hermetic seal. Additionally, a thermally stable sealant can be disposed in between the protrusions and the grooves. Dependent upon the material chosen, the sealant can prevent a hermetic seal, but can create a ‘near-hermetic’ seal that would be better at absorbing stresses. The sides 413 and sidewalls 414 can form an angle between twenty-five and thirty-five degrees, as measured from a line that is perpendicular to the top 415 of the protrusion 311 and the bottom 416 of the groove 312, respectively. Continuing with this theme, the sides 413 and sidewalls 414 can also form an angle between twenty and forty degrees, or fifteen and forty-five degrees, or ten and fifty degrees, or five and fifty-five degrees, as measured from the same perpendicular line.

The sidewalls 414 of the grooves can comprise a dielectric material while the bottom 416 of the groove can comprise an electrically conductive pad. The protrusions 311 can comprise an electrically conductive material, or the sides can comprise a dielectric material and the top 415 can comprise an electrically conductive pad. A pitch can exist between the electrically conductive protrusions and pads, the pitch measuring less than one-hundred fifty nanometers.

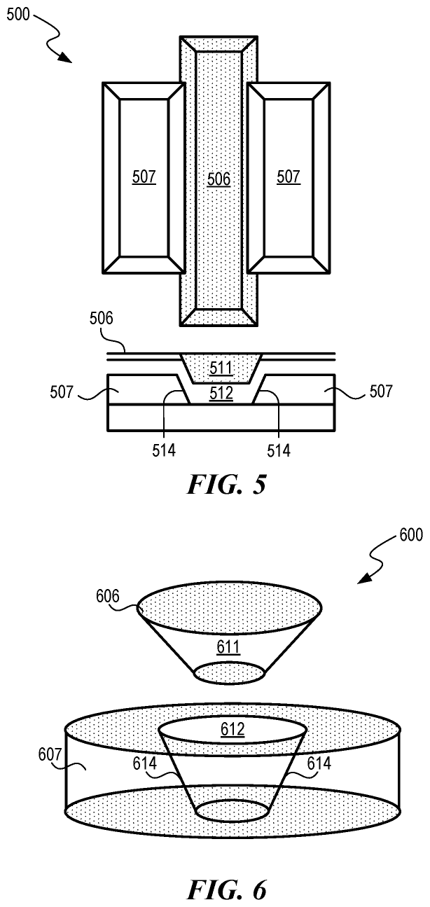

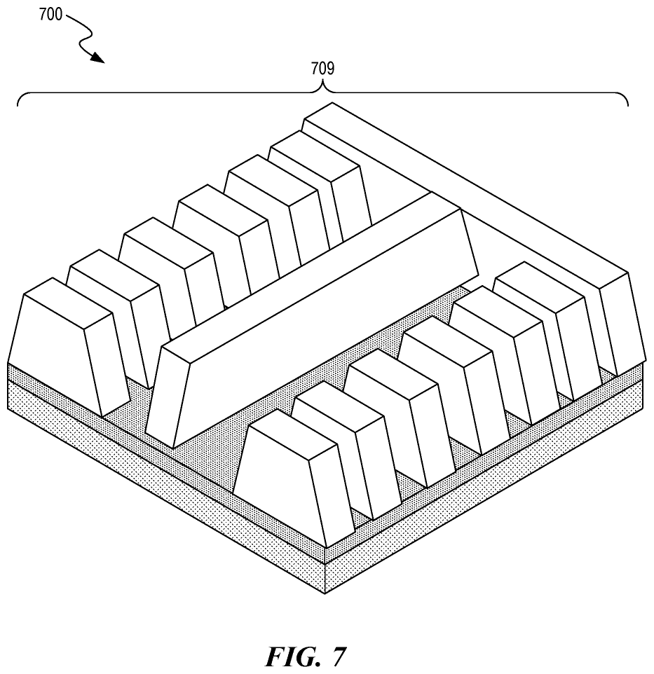

FIG. 5 and FIG. 6 are simplified schematic cross-sectional views of a section of a semiconductor device assembly in accordance with embodiments of the present technology. In FIG. 5, the protrusions 511 have a profile with a trapezoid shape, while the grooves 512 have planar sidewalls 514 to match this shape. In FIG. 6 the protrusions 611 have a shape, and the shape is that of an inverted cone frustum, while the grooves 612 have curved sidewalls 614 to match this shape.

In all of the previous illustrations, the pattern of protrusions and grooves within the mechanical alignment structure have been relatively simple, with one alternating after the other. However, this simplicity has partly been a bias of the flat cross-sectional perspective, as these mechanical alignment structures can form more complicated patterns, designed either by formula or by deep learning neural network to maximize the available bonding surface area between substrates. In FIG. 7, illustrated from an oblique point of view, a potential embodiment of the present technology is illustrated in which a substrate 700 has a more complicated mechanical alignment structure 709. This substrate 700 could be a wafer forming one layer of a WoW stack, in which a separate wafer with a matching mechanical alignment structure is disposed on top of it, such that the mechanical alignment structures of both wafers inter-fit and bonding regions are formed between them.

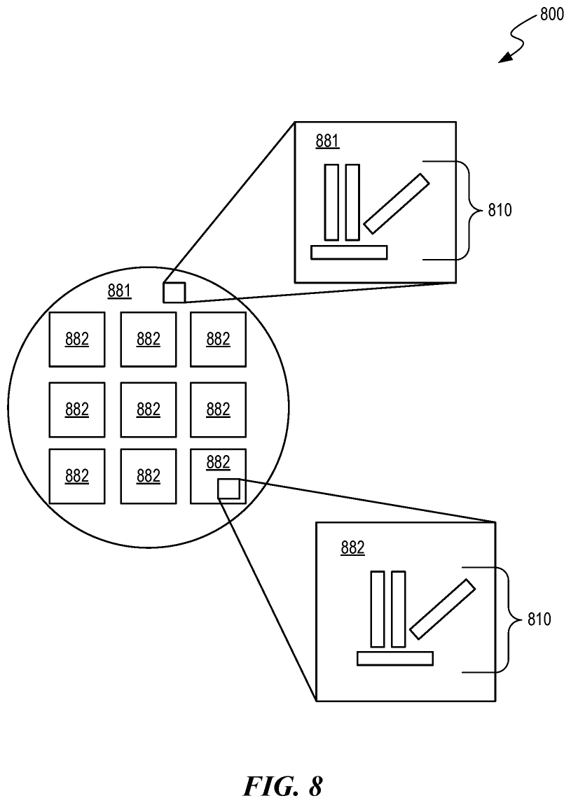

In the foregoing illustrated embodiments, the substrates could have been wafers which had been bonded together. FIG. 8 illustrates such a potential embodiment, showing a wafer 800 which includes semiconductor devices 882 separated by a scribe area 881. In such an embodiment, a mechanical alignment structure 810 can exist either within the scribe area 881, or within a semiconductor die 882, or in both areas. This mechanical alignment structure could be composed of dielectric material, oxide, silicon, electrically conductive material, etc.

The substrates from the foregoing illustrations could have been CMOS wafers, Array wafers, a stack of DRAM with TSVs forming a cube, a stack of NAND, or any two semiconductor devices, including a controller, an optical sensor, etc.

Although in the foregoing example embodiments semiconductor device assemblies have been illustrated and described as including a single semiconductor device, in other embodiments assemblies can be provided with additional semiconductor devices. For example, the single semiconductor devices illustrated in FIGS. 2, 7, 8, 9, and/or 10 could be replaced with, e.g., a vertical stack of semiconductor devices, a plurality of semiconductor devices, mutatis mutandis.

Although in the foregoing example embodiments semiconductor device assemblies have been illustrated and described as including mechanical alignment structures formed by etching a dielectric material to form grooves and/or protrusions, in other embodiments additive processes may be used to form the mechanical alignment structures, or a mixture of additive and subtractive processes (e.g., plating a pillar forming the top of a protrusion and then depositing material around the protrusion to form a tapered dielectric sheathing, etc.). Moreover, although the foregoing examples have illustrated one surface as including protrusions and a facing surface including grooves, in other embodiments a single surface can include a mix of protrusions and grooves, with the facing surface including a corresponding mix of matching grooves and protrusions.

In accordance with one aspect of the present disclosure, the semiconductor devices illustrated in the assemblies of FIGS. 2-10 could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

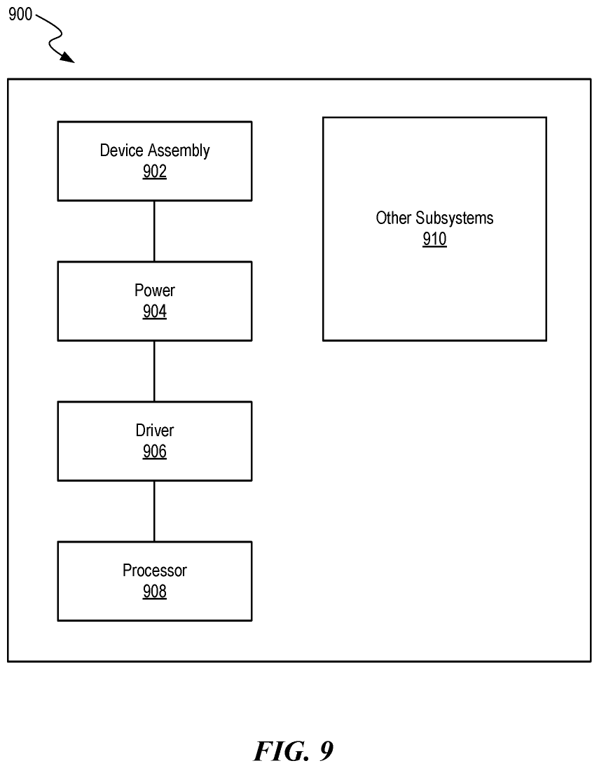

Any one of the semiconductor apparatuses and incorporated semiconductor apparatuses described above with reference to FIGS. 2-8 can be incorporated into any of a myriad of larger and/or more complex systems, a representative example of which is system 900 shown schematically in FIG. 9. The system 900 can include a semiconductor device assembly (e.g., or a discrete semiconductor device) 902, a power source 904, a driver 906, a processor 908, and/or other subsystems or components 910. The semiconductor device assembly 902 can include features generally similar to those of the semiconductor devices described above with reference to FIGS. 2-8. The resulting system 900 can perform any of a wide variety of functions, such as memory storage, data processing, and/or other suitable functions. Accordingly, representative systems 900 can include, without limitation, hand-held devices (e.g., mobile phones, tablets, digital readers, and digital audio players), computers, vehicles, appliances and other products. Components of the system 900 may be housed in a single unit or distributed over multiple, interconnected units (e.g., through a communications network). The components of the system 900 can also include remote devices and any of a wide variety of computer readable media.

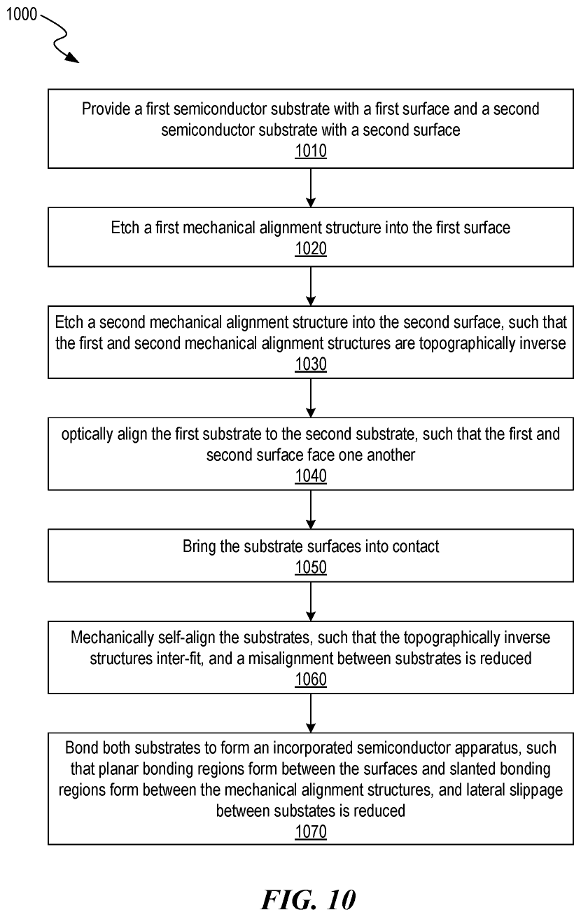

FIG. 10 is a flow chart illustrating a method for mechanical self-alignment and slip-resistance in bonding semiconductor substrates. The method includes providing a first semiconductor substrate with a first surface and a second semiconductor substrate with a second surface (box 1010). The method further includes etching a first mechanical alignment structure into the first surface (box 1020). The method further includes etching a second mechanical alignment structure into the second surface, such that the first and second mechanical alignment structures are topographically inverse (box 1030). The method further includes optically aligning the first substrate to the second substrate, such that the first and second surface face one another (box 1040). The method further includes bringing the substrate surfaces into contact (box 1050). The method further includes mechanically self-aligning the substrates, such that the topographically inverse structures inter-fit (box 1060). The method further includes bonding both substrates to form planar bonding regions between the surfaces and slanted bonding regions between the mechanical alignment structures (box 1070).

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A method for mechanical self-alignment and slip-resistance in bonding semiconductor substrates, the method comprising:
providing a first semiconductor substrate with a first surface and a second semiconductor substrate with a second surface;
etching a first mechanical alignment structure into the first surface;
etching a second mechanical alignment structure into the second surface, such that the first and second mechanical alignment structures are topographically inverse;
optically aligning the first substrate to the second substrate, such that the first and second surface face one another;
bringing the substrate surfaces into contact;
mechanically self-aligning the substrates, such that the topographically inverse structures inter-fit;
bonding both substrates to form planar bonding regions between the surfaces and slanted bonding regions between the mechanical alignment structures.

2. The method of claim 1, wherein at least the first semiconductor substrate is a wafer, and the method further comprises dicing the first semiconductor substrate to form a stacked semiconductor device assembly.

3. The method of claim 2, wherein the first mechanical alignment structures is disposed a scribe line of the wafer.

4. The method of claim 1, wherein the first and second surfaces comprise micro-patterning in the planar bonding regions.

5. The method of claim 1, wherein at least one of the mechanical alignment structures is vertically aligned with circuitry of the first or second semiconductor substrate.

6. The method of claim 1, wherein the first and second surfaces each comprise at least one of the following materials: a dielectric material, an oxide, silicon, or an electrically conductive material.

7. The method of claim 1, wherein the first mechanical alignment structure is atomically bonded with the second mechanical alignment structure to form a hermetic seal.

8. The method of claim 1, wherein a thermally stable sealant is disposed in between the first and second mechanical alignment structures.

9. The method of claim 1, wherein the first mechanical alignment structure has protrusions, each protrusion having a top and sides, and wherein the second mechanical alignment structure has grooves, each groove having a bottom and sidewalls.

10. The method of claim 9, wherein the protrusions are inverted conical frustums and the grooves have curved sidewalls.

11. The method of claim 9, wherein the protrusions have a profile with a trapezoid shape, and wherein the grooves have planar sidewalls.

12. The method of claim 9, wherein the sides and sidewalls each have an angle of thirty degrees, as measured from a line that is perpendicular to the top of the protrusion and the bottom of the groove, respectively.

13. The method of claim 9, wherein bringing the substrate surfaces into contact comprises bringing the sides of the protrusions into contact with the sidewalls of the grooves.

14. The method of claim 9, wherein the first and second surface comprise a dielectric material, the sidewalls of the grooves comprise the same dielectric material, the bottoms of the grooves comprise an electrically conductive pad, and the protrusions comprise an electrically conductive material.

15. The method of claim 14, wherein a pitch between the electrically conductive protrusions and pads measures less than one-hundred fifty nanometers.

16. A semiconductor apparatus comprising:
a first semiconductor substrate including a first dielectric surface having a first mechanical alignment structure with protrusions, each protrusion having a top and sides;
a second semiconductor substrate including a second dielectric surface in contact with the first surface, the surface having a second mechanical alignment structure with grooves, each groove having sidewalls and a bottom, wherein the second mechanical alignment structure is a topographic inverse of the first mechanical alignment structure, so that the protrusions and grooves are inter-fitted;
planar bonding regions between the first and second surface; and
slanted bonding regions between the sides and sidewalls,
wherein the protrusions comprise a dielectric material or electrically conductive pads, wherein the bottoms of the grooves comprise a dielectric material or electrically conductive pads, and
wherein a pitch exists between the electrically conductive pads, the pitch measuring less than one-hundred fifty nanometers.

17. The semiconductor apparatus of claim 16, wherein at least one of the first and second substrates is a wafer, and wherein at least one of the corresponding first or second mechanical alignment structures is located in a plan area of a semiconductor device surrounded by scribe lines.

18. The semiconductor apparatus of claim 16, wherein at least one of the first and second substrates is a singulated semiconductor device.

19. A semiconductor apparatus, comprising:
a substrate including a dielectric surface at which is formed a plurality of mechanical alignment structures, each with a horizontal surface offset from the dielectric surface and side surfaces at an angle of thirty degrees, as measured from a line that is perpendicular to the dielectric surface,
wherein the protrusions comprise a dielectric material or electrically conductive pads,
wherein the bottoms of the grooves comprise a dielectric material or electrically conductive pads, and
wherein a pitch between the plurality of mechanical alignment structures measures less than one-hundred fifty nanometers.

20. The semiconductor apparatus of claim 19, wherein the semiconductor substrate is a wafer, and at least one of the mechanical alignment structures is located in a plan area of a semiconductor device surrounded by scribe lines.
